(19) United States
(12) Patent Application Publication
(10) Pub. No.: US 2008/0276986 A1
(43) Pub. Date: Nov. 13, 2008

(54) Photolithography Method For Contacting Thin-Film Semiconductor Structures

(75) Inventors: Armin Gerhard Aberle, Botany, New South Wales (AU); Timothy Michael Walsh, Victoria (AU); Daniel A. Inns, New South Wales (AU)

Correspondence Address: CARTER, DELUCA, FARRELL & SCHMIDT, LLP, 445 BROAD HOLLOW ROAD, SUITE 225, MELVILLE, NY, 11747, US

(73) Assignee: NEWSOUTH INNOVATIONS PTY LIMITED, New South Wales (AU)

(21) Appl. No.: 11/908,760

(22) PCT Filed: Feb. 28, 2006
(86) PCT No.: PCT/AU2006/000254

§ 371 Date: Mar. 26, 2008

(30) Foreign Application Priority Data
Mar. 16, 2005 (AU) 2005901285

(51) Int. Cl. H01L 31/00; H01L 21/00

(52) U.S. Cl. 136/256; 438/80; 257/E21.001; 257/E31.001

(57) ABSTRACT

A photolithography method for contacting one or more contact regions of a thin-film semiconductor structure on a transparent supporting material is disclosed. The method comprises the steps of forming one or more openings (6a) in the semiconductor structure (2, 3, 4) to substantially expose respective surface portions (5a) of the supporting material (5) and respective contact regions (4a); covering the surface of the semiconductor structure with a positive photoresist (7); illuminating the semiconductor structure with an exposing light through the supporting material such that first portions of the photoresist covering the substantially exposed surface portions of the supporting material and at least portions of the contact regions respectively are exposed to the exposing light and such that the exposing light is absorbed in the semiconductor structure, leaving one or more second portions of the photoresist covering the semiconductor structure unexposed. Preferably, a conductive layer (9) is deposited over the remaining second portions of the photoresist, the surface portions (5a) of the supporting material, and at least portions of the contact regions, such that the conductive layer may be in contact with the supporting substrate and making electrical contact with the contact regions. Preferably, the remaining second portions of the photoresist are chemically dissolved, and portions of the conductive layer sitting above the second portions of the photoresist are lifted off, leaving remaining portions of the conductive layer in contact with the supporting substrate and making electrical contact with the contact regions.

### FIELD OF INVENTION

The present invention relates broadly to a photolithography method for contacting one or more contact regions of a thin-film semiconductor structure on a transparent supporting material.

### BACKGROUND

Thin-film semiconductor structures have found application in a variety of devices, and it is believed that thin-film semiconductor structures will be significant in the development of future devices. For example, thin-film solar cells have the potential to generate solar electricity at much lower cost than is possible with conventional, wafer-based technology. This is primarily due to two factors. Firstly, if deposited onto a textured supporting substrate or superstrate, the amount of semiconductor material in the solar cells can be greatly reduced, with little penalty in the cell's energy conversion efficiency. Secondly, thin-film solar cells can be manufactured on large-area substrates (e.g. about 1 m²), streamlining the production process and further reducing processing cost.

A crucial step in the fabrication of thin-film solar cells is the contacting of the top and bottom semiconductor diode layers, which is often referred to as metallisation of the thin-film solar cells. While various techniques have been proposed involving known thin-film fabrication techniques such as photolithography processes utilizing sacrificial mask structures, there remains a need to provide more streamlined production processes, more accurate production processes, or both.

### SUMMARY

In accordance with a first aspect of the present invention there is provided a photolithography method for contacting one or more contact regions of a thin-film semiconductor structure on a transparent supporting material, the method comprising forming one or more openings in the semiconductor structure to substantially expose respective surface portions of the supporting material and respective contact regions; covering the surface of the semiconductor structure with a positive photoresist; and illuminating the semiconductor structure with an exposing light through the supporting material such that first portions of the photoresist covering the substantially exposed surface portions of the supporting material and at least portions of the contact regions respectively are exposed to the exposing light and such that the exposing light is absorbed in the semiconductor structure leaving one or more second portions of the photoresist covering the semiconductor structure free from exposure.

The semiconductor structure may be a solar cell comprising a large-area diode structure having at least one p-type and one n-type heavily doped layer, and the contact region comprises a portion of either the p-type or the n-type heavily doped layers.

The contact regions may each comprise at least a portion of one of the p-type or the n-type heavily doped layers closer to the supporting material.

The openings in the semiconductor structure may be formed by etching of the semiconductor structure.

The method used in the etching may comprise one or more of a group consisting of plasma etching, reactive ion etching, wet chemical etching, and dry chemical etching.

The openings in the semiconductor structure may be formed by laser ablation of the semiconductor structure.

Regions of the semiconductor structure to be removed to form the openings may be defined by an etch mask.

The etch mask may also act as a top electrode of the semiconductor structure.

The top electrode may make electrical contact with a top heavily doped layer of the semiconductor structure.

The top electrode may comprise a layer of metal.

The top electrode may comprise a layer of transparent conductive oxide.

The photoresist may be developed after the illumination step such that the exposed first portions of the photoresist are dissolved and removed.

A conductive layer may be deposited over the remaining second portions of the photoresist, the surface portions of the supporting material, and at least portions of the contact regions, such that the conductive layer may be in contact with the supporting substrate and making electrical contact with the contact regions.

The remaining second portions of the photoresist may be chemically dissolved, and portions of the conductive layer sitting above the second portions of the photoresist may be lifted off, leaving remaining portions of the conductive layer in contact with the supporting substrate and making electrical contact with the contact regions.

The conductive layer may comprise a metal layer.

The conductive layer may comprise a transparent conductive oxide layer.

The method may further comprise widening of openings in the etch mask above the openings in the semiconductor structure by chemical etching prior to depositing the photoresist.

The exposed heavily doped semiconductor layer and a corresponding thickness of semiconductor material on sidewalls of the formed openings in the semiconductor structure may be removed by chemical etching prior to depositing the photoresist.

The top contact layer may comprise a plurality of finger portions connected to a busbar portion, and the openings may be formed by removing semiconductor material between adjacent pairs of the finger portions.

The semiconductor structure may be silicon based.

The supporting material may comprise glass or glass ceramic.

The supporting material may function as a substrate or a superstrate for the semiconductor structure.

The supporting material may be coated with a transparent or semi-transparent film.

In accordance with a second aspect of the present invention there is provided a thin-film semiconductor structure fabricated utilising the method as defined in the first aspect.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic top view of a semiconductor diode structure with top contact layer for use in a method of making electrical contact to thin-film solar cells according to an embodiment of the present invention.

FIGS. 2 to 8 are schematic cross-sectional views of the semiconductor diode structure of FIG. 1 after different processing steps of the method of making electrical contact to thin-film solar cells according to an example embodiment.

FIG. 9 shows a flowchart illustrating a photolithography method for contacting one or more contact regions of a thin-film semiconductor structure on a transparent supporting material, according to an example embodiment.

### DETAILED DESCRIPTION

Embodiments of the present invention provide a self-aligning, maskless photolithography method for contacting thin-film semiconductor structures on transparent supporting materials.

The example embodiment described below provides a method for making electrical contact to a thin-film solar cell on a transparent insulating supporting material. The supporting material acts either as the substrate or the superstrate of the solar cell. The supporting material may be (but is not limited to) glass or a glass ceramic. In the example embodiment, the supporting material is a glass substrate. The solar cell structure may be (but is not limited to) a n⁺πp⁺ or a p⁺πn⁺ thin-film diode structure in the example embodiment, where π represents a lightly doped absorber layer (either n-type or p-type or undoped). A thin dielectric (i.e., transparent or semi-transparent, and insulating) barrier layer, such as silicon nitride, silicon oxide, or a transparent conductive oxide, may be formed on the glass substrate to minimise outdiffusion of contaminants from the glass into the solar cell during solar cell manufacture. This dielectric layer may also act as an anti-reflective coating if the solar cell is to be used in superstrate configuration.

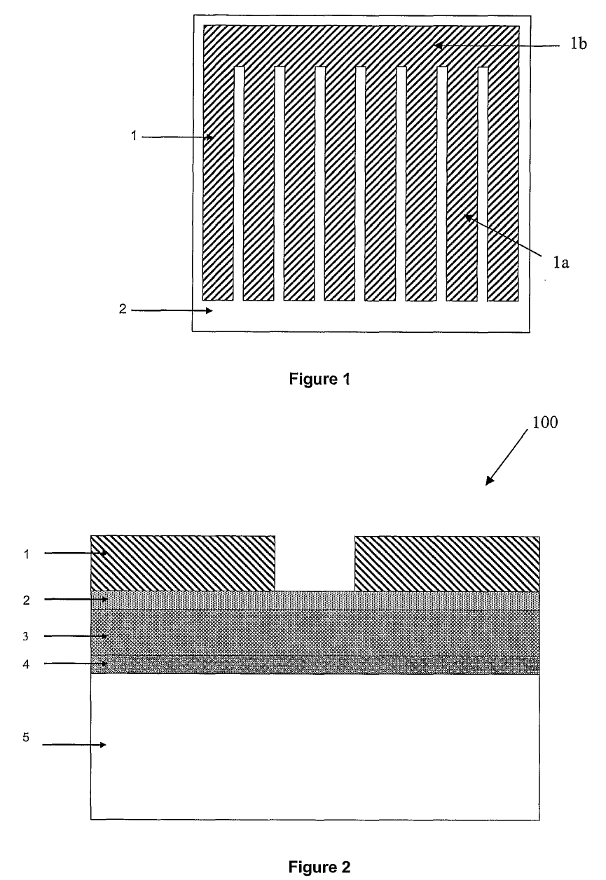

FIG. 1 shows a top view of a patterned conducting layer in the form of a layer of metal (1) which is deposited onto the surface layer (2) of a thin-film semiconductor diode on a transparent glass substrate. The layer of metal (1) may be of a thickness of about 0.1 μm to 100 μm. The pattern in the metal (1) may be achieved by evaporating or sputtering aluminium through a suitable shadow mask (but other materials, methods of patterning, or both, may be applied). The pattern of the metal (1) is chosen to be appropriate to making electrical contact to the large-area thin-film diode structure, and hence may be of the form of fingers (1a) and a busbar (1b).

FIG. 2 shows a cross-sectional view of the thin-film solar cell structure 100 comprising a glass-side heavily doped layer (4), a lightly doped absorber (3) and an air-side heavily doped layer (2) on a transparent insulating substrate (5). The patterned metal top contact (1) has been deposited onto the air-side heavily doped layer (2). In one p⁺nn⁺ crystalline silicon thin-film solar cell on glass in an example embodiment, the glass-side heavily doped layer (4) is n⁺ type, the lightly doped absorber (3) is n-type, and the air-side heavily doped layer (2) is p⁺-type. The fabrication of the p⁺nn⁺ crystalline silicon thin-film solar cell on glass can be performed with known fabrication techniques. For example, solid phase crystallisation (SPC) of amorphous silicon at temperatures around 600° C. can be used, as shown by Matsuyama et al. (High-quality polycrystalline silicon thin film prepared by a solid phase crystallisation method, Journal of Non-crystalline Solids 198-200, 1996, pages 940-944, the content of which is hereby incorporated by reference).

Next, etching through the thin-film diode structure (2, 3, 4) is performed, using the patterned layer of metal (1) as an etch mask. The etching may be achieved by plasma etching or reactive ion etching (RIE), but is not limited to these techniques. Wet or dry chemical etching may, for example, instead be used in different embodiments. Alternatively, laser ablation may be used to form openings in the thin-film diode structure (2, 3, 4).

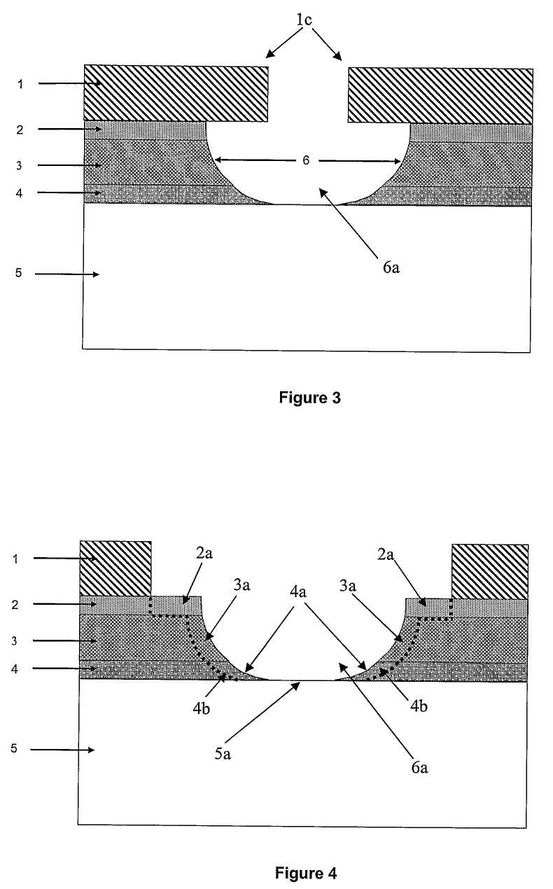

FIG. 3 shows a cross-sectional view of the device after the semiconductor diode structure (2, 3, 4) has been etched through, forming opening (6a). The sidewalls (6) of the opening (6a) are shown to be curved, as they would be if the etching process is isotropic in an example embodiment. However, it will be appreciated that the sidewalls (6) may have a different shape/texture depending on the techniques used to form the etched region.

In the example embodiment, overhanging metal, e.g. (1c) resulting from under-etching is then removed. This may, for example, be achieved by means of wet-chemical etching. FIG. 4 shows a cross-sectional view of the device after the overhanging parts of metal layer (1) have been removed. A surface region (5a) of the transparent substrate (5) is exposed at the bottom part of the opening (6a), as well as portions (4a) of the glass-side heavily doped layer (4).

A brief semiconductor etching step may be added that eliminates the exposed top heavily doped semiconductor layer portions (2a) in FIG. 4, together with a corresponding thickness of semiconductor material (3a, 4b) on the sidewalls of the thin-film diode structure. This may, for example, be achieved by means of wet-chemical etching in a solution containing water, hydrofluoric acid, and potassium permanganate. The purpose of this brief etching step is to reduce the risk of electrical shunting between the bottom and top heavily doped semiconductor layers (4) and (2) respectively by the structured metal film created in the example embodiment (compare (9) in FIG. 8).

Next, self-aligning maskless photolithography is performed to coat the bottom of the etched regions with a thin metal film and thereby make electrical contact to the bottom (glass side) heavily doped layer, in the example embodiment.

As shown in FIG. 5, a layer of positive photoresist (7) such as, but not limited to, Shipley Microposit 1818 photoresist is deposited over the surface of the sample and pre-baked, for example for 30 minutes at 90° C. The photoresist (7) may be deposited by spin-coating in the example embodiment, but is not limited to that technique. The photoresist (7) is exposed to UV light (8) from the glass side of the solar cell, such that the semiconductor films (4), (3), (2) act as a self-aligned photomask. The UV light (8) thus first passes through the transparent substrate (5). In the example embodiment, crystalline silicon has a very high absorption coefficient α for UV light. Specifically, α_{Si} is about 10⁸ m⁻¹ for UV light and therefore the UV light (8) does not penetrate through silicon films that are thicker than about 50 nm. The silicon layers (4), (3), (2) used in the example embodiment are thicker than 50 nm. In one example embodiment the heavily doped layers (4), (2) are each approximately 50 nm thick, and the lightly doped π-layer (3) is approximately 2 μm thick. As a result, only portions of the photoresist (7) are exposed to the UW light (8), more particularly those portions covering the substantially exposed surface portion (5a) of the transparent substrate (5) and portions of the regions (4a) of the glass-side heavily doped layer (4).

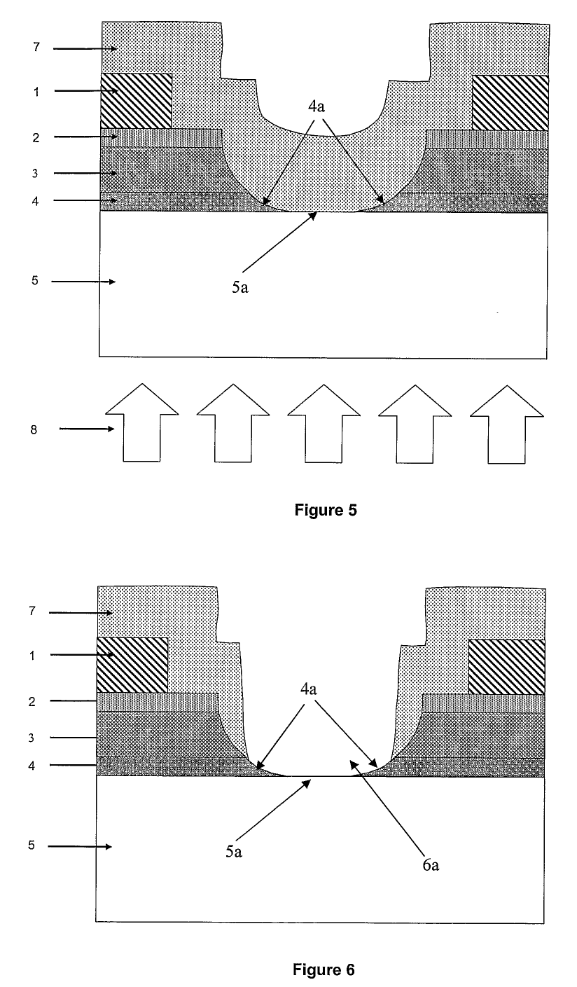

Next, the photoresist (7) is developed to remove the exposed portions, and FIG. 6 shows a cross-sectional view of the device after the photoresist (7) has been removed from the opening (6a). Post-baking of the photoresist (7) is then performed, for example at 120° C. for 30 minutes. As can be seen from FIG. 6, the surface region (5a) of the transparent substrate (5) and portions of the regions (4a) of the glass-side heavily doped layer (4) are now free from coverage by the photoresist (7).

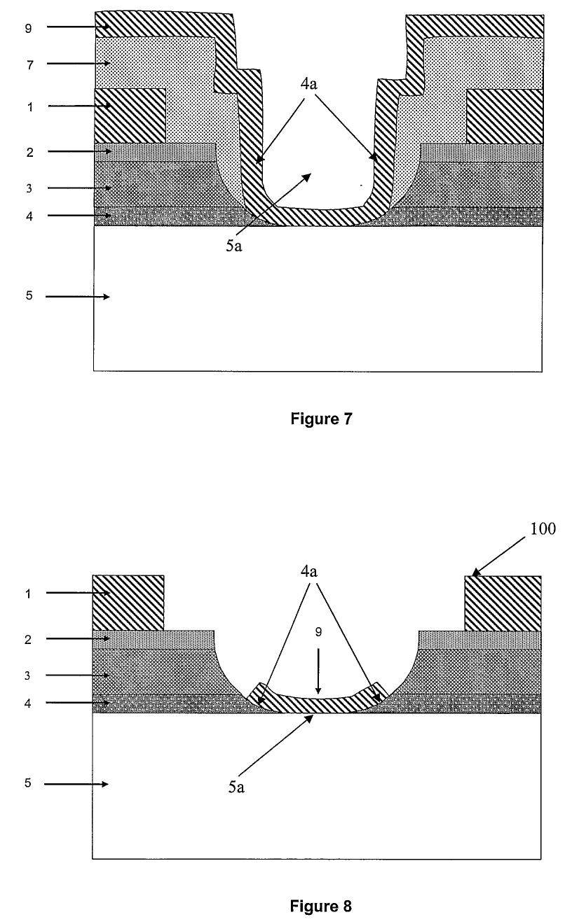

A layer of metal (9) e.g. aluminium is e.g. sputtered or evaporated over the surface of the device. The layer of metal (9) may be of a thickness of about 0.1 μm to 1 μm. FIG. 7 shows a cross-sectional view of the device after the layer of metal (9) has been deposited over the top surface. The remaining photoresist (7) is then dissolved chemically in the example embodiment and hence the portions of metal (9) which are on top of the remaining photoresist (7) are lifted off, leaving metal (9) only on the surface portion (5a) of the transparent substrate (5) and contact sections of the portions (4a) of the glass-side heavily doped layer (4), thus making electrical contact to the glass-side heavily doped layer (4), as shown in FIG. 8.

The solar cell structure 100 now has two metal electrodes, metal (1) contacting the top, air-side heavily doped layer (2), and metal (9) contacting the bottom, glass-side layer heavily doped layer (4). Whichever initial diode structure was used, the device now has one positive electrode which is contacting the p-type heavily doped layer, and another negative electrode which is contacting the n-type heavily doped layer.

The fabrication method described in the example embodiment with reference to FIGS. 1 to 8 can have a number of advantages, including maskless fabrication of one electrode, and a self-alignment between that one electrode and the other, first-formed electrode. This can provide a more streamlined and more accurate production process compared to existing processes.

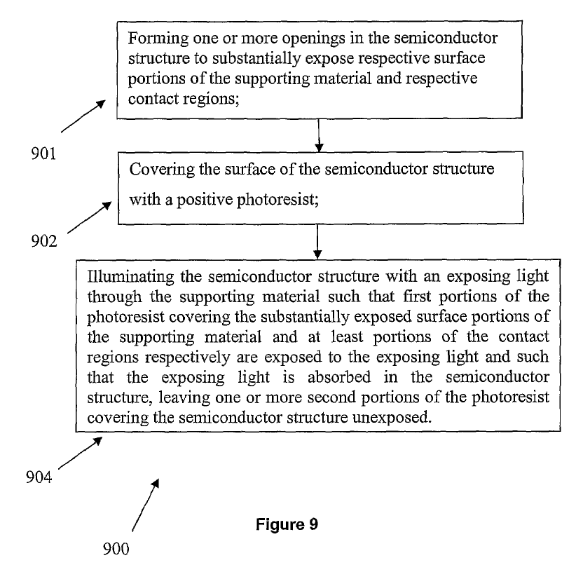

FIG. 9 shows a flowchart 900 illustrating a photolithography method for contacting one or more contact regions of a thin-film semiconductor structure on a transparent supporting material, according to an example embodiment. At step 901, one or more openings are formed in the semiconductor structure to substantially expose respective surface portions of the supporting material and respective contact regions. At step 902, the surface of the semiconductor structure is covered with a positive photoresist. At step 904, the semiconductor structure is illuminated with an exposing light through the supporting material such that first portions of the photoresist covering the substantially exposed surface portions of the supporting material and at least portions of the contact regions respectively are exposed to the exposing light and such that the exposing light is absorbed in the semiconductor structure leaving one or more second portions of the photoresist covering the semiconductor structure unexposed.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

For example, while the present invention has been described herein with reference to an example embodiment for making electrical contact to a thin-film solar cell, it will be appreciated that the invention does have broader applications to other thin-film semiconductor structures such as thin-film transistors, liquid crystal cells, etc.

Furthermore, other materials may be used for the electrodes, including, but not limited to, transparent conductive oxides.

What is claimed is:

1. A photolithography method for contacting one or more contact regions of a thin film semiconductor structure on a transparent supporting material, the method comprising:
forming one or more openings in the semiconductor structure to substantially expose respective surface portions of the supporting material and respective contact regions;
covering the surface of the semiconductor structure with a positive photoresist; and
illuminating the semiconductor structure with an exposing light through the supporting material such that first portions of the photoresist covering the substantially exposed surface portions of the supporting material and at least portions of the contact regions respectively are exposed to the exposing light and such that the exposing light is absorbed in the semiconductor structure, leaving one or more second portions of the photoresist covering the semiconductor structure unexposed.

2. The method as claimed in claim 1, wherein the semiconductor structure is a solar cell comprising a large-area diode structure having at least one p-type and one n-type heavily doped layer, and the contact region comprises a portion of either the p-type or the n-type heavily doped layers.

3. The method as claimed in claim 2, wherein the contact regions each comprise at least a portion of the one of the p-type or the n-type heavily doped layers which is closer to the supporting material.

4. The method as claimed in claim 1, wherein the openings in the semiconductor structure are formed by etching of the semiconductor structure.

5. The method as claimed in claim 4, wherein the method used in the etching comprises one or more of a group consisting of plasma etching, reactive ion etching, wet chemical etching, and dry chemical etching.

6. The method as claimed in claim 1, wherein the openings in the semiconductor structure are formed by laser ablation of the semiconductor structure.

7. The method as claimed in claim 1, wherein regions of the semiconductor structure to be removed to form the openings are defined by an etch mask.

8. The method as claimed in claim 7, wherein the etch mask also acts as a top electrode of the semiconductor structure.

9. The method as claimed in claim 8, wherein the top electrode makes electrical contact with a top heavily doped layer of the semiconductor structure.

10. The method as claimed in claim 7, wherein the top electrode comprises a layer of metal.

11. The method as claimed in claim 7, wherein the top electrode comprises a layer of transparent conductive oxide.

12. The method as claimed in claim 1, wherein the photoresist is developed after the illuminating step such that the exposed first portions of the photoresist are dissolved and removed.

13. The method as claimed in claim 12, wherein a conductive layer is deposited over the remaining second portions of the photoresist, the surface portions of the supporting material, and at least portions of the contact regions, such that the conductive layer is in contact with the supporting substrate and making electrical contact with the contact regions.

14. The method as claimed in claim 13, wherein the remaining second portions of the photoresist are chemically dissolved, and portions of the conductive layer sifting above the second portions of the photoresist are lifted off, leaving remaining portions of the conductive layer in contact with the supporting substrate and making electrical contact with the contact regions.

15. The method as claimed in claim 1, wherein the conductive layer comprises a metal layer.

16. The method as claimed in claim 1, wherein the conductive layer comprises a transparent conductive oxide layer.

17. The method as claimed in claim 7, further comprising widening of openings in the etch mask above the openings in the semiconductor structure by chemical etching prior to depositing the photoresist.

18. The method as claimed in claim 9, wherein the exposed heavily doped semiconductor layer and a corresponding thickness of semiconductor material on sidewalls of the formed openings in the semiconductor structure are removed by chemical etching prior to depositing the photoresist.

19. The method as claimed in claim 9, wherein the top contact layer comprises a plurality of finger portions connected to a busbar portion, and the openings are formed by removing semiconductor material between adjacent pairs of the finger portions.

20. The method as claimed in claim 1, wherein the semiconductor structure is silicon based.

21. The method as claimed in claim 1, wherein the supporting material comprises glass or glass ceramic.

22. The method as claimed in claim 1, wherein the supporting material functions as a substrate or a superstrate for the semiconductor structure.

23. The method as claimed in claim 1, wherein the supporting material is coated with a transparent or semi-transparent film.

24. A thin-film semiconductor structure fabricated utilising the method as claimed in claim 1.
